(19) United States
(12) Patent Application Publication
(10) Pub. No.: US 2002/0025673 A1
(43) Pub. Date: Feb. 28, 2002

(54) Method for forming gate by using Co-silicide

(76) Inventors: Woon Young Song, Kyoungki-do (KR); Bum Jin Jun, Kyoungki-do (KR); Jae Young Kim, Kyoungki-do (KR)

Correspondence Address: PILLSBURY WINTHROP LLP, 1600 TYSONS BOULEVARD, MCLEAN, VA, 22102, US

(21) Appl. No.: 09/737,803

(22) Filed: Dec. 18, 2000

(30) Foreign Application Priority Data
Dec. 17, 1999 (KR) 99-58821

(51) Int. Cl. H01L 21/4763; H01L 21/44

(52) U.S. Cl. 438/649; 438/652

(57) ABSTRACT

The present invention discloses a method for forming a gate having a stacked structure, including a lower polysilicon layer and an upper Co-silicide layer, by etching the stacked layers using a hard mask film as an etching mask. The etching process is performed by maintaining a temperature of a wafer chuck in an etching chamber where a substrate is positioned, namely an electrode temperature over 70° C., preferably between 70 and 300° C., and by using Cl₂ base gas. In addition, at least one gas selected from the group consisting of Ar, HBr, O₂ and He—O₂ may be mixed with the Cl₂ gas.

### BACKGROUND OF THE INVENTION

1. Field of the Invention

The present invention relates to a method for forming a gate for a semiconductor device and, in particular, to a method for forming a gate having a stacked structure comprising layers of polysilicon and Co-silicide.

2. Description of the Background Art

Single layers of polysilicon and stacked layers of polysilicon and W-silicide have long been employed as gate materials for MOSFET devices. As developments increase the level of integration of semiconductor devices the gate width continues to be reduced as well, making it difficult to obtain sufficiently low resistance using a gate structure comprising, the single layer of the polysilicon or the stacked layer of the polysilicon and W-silicide. One alternative that has been suggested is a gate structure using a Ti-silicide instead of the W-silicide in order to lower the gate resistance.

The Ti-silicide layer, however, tends to increase the gate resistance due to large numbers of pores generated in the layer during subsequent thermal processes such as annealing processes. These pores are generated mostly in step regions, i.e., those regions where the gate line moves between a device isolating region and an active region. In addition, the pores tend to be generated more significantly during annealing processes using a furnace than those using a rapid thermal treatment. The upper Ti-silicide layer also reacts with the lower polysilicon layer at their interface during the annealing process and during subsequent thermal processes. Accordingly, the thickness of the Ti-silicide layer is irregular, and the surface roughness of the polysilicon layer is increased, thereby degrading both the gate electrical properties and the device reliability.

Various barrier layers have been proposed for preventing the interface reaction between the polysilicon layer and the Ti-silicide layer. These barrier layers have included an amorphous silicon layer, a titanium nitride (TiN) layer, a titanium silicon nitride (TiSiN) layer and a tungsten nitride (WN) layer between the polysilicon layer and the Ti-silicide layer. These barrier layers however, have proven insufficient to prevent the undesirable increases in the gate resistance, and the accompanying degradation in the gate electrical properties and device reliability. As a result, a Ti-silicide layer has not proven to be suitable for gate material.

Accordingly, researchers have continued their efforts to identify an improved, low resistance gate material. For example, a Co-silicide has been considered as a substitute for the Ti-silicide. A gate consisting of the Co-silicide can provide sufficiently low resistance at even minute gate line widths. Further, however, an etching chemistry effective with the Co-silicide had not been developed, thus it rendering difficult, if not impossible, to utilize the Co-silicide as an effective gate material.

### SUMMARY OF THE INVENTION

Accordingly, an object of the present invention is to provide a method for forming a gate having a stacked structure of a polysilicon and a Co-silicide, specifically by suggesting an effective etching chemistry for the Co-silicide.

In order to achieve the above-described object of the present invention, the present invention provides a method for forming a gate structure in which a polysilicon layer and a Co-silicide layer are stacked. This method provides a way to etch the Co-silicide layer, the polysilicon layer, and the gate oxide layer. Specifically, the etching process involves maintaining an electrode temperature of more than 70° C. in the etching chamber, and using Cl₂ as the base etching gas.

The present invention may be better understood with reference to the detailed description accompanying figures. The figures in particular are only for purposes of illustration and thus do not operate to unduly limit of the present invention.

### BRIEF DESCRIPTION OF THE DRAWINGS

FIGS. 1A through 1C are cross-sectional diagrams illustrating certain of the sequential steps of a method for forming a gate having a stacked structure of a polysilicon layer and a Co-silicide layer in accordance with a preferred embodiment of the present invention; and

FIGS. 2 and 3 are photographs showing the dependence on an electrode temperature in a state where a gate conductive layer including the Co-silicide layer is etched using Cl₂ base gas in accordance with the preferred embodiment of the present invention, wherein:

FIG. 2 is a photograph showing an etching result when the electrode temperature in an etching chamber is about 30° C.; and

FIG. 3 is a photograph showing an etching result when the electrode temperature in the etching chamber is about 70° C.

### DETAILED DESCRIPTION OF THE PREFERRED EMBODIMENTS

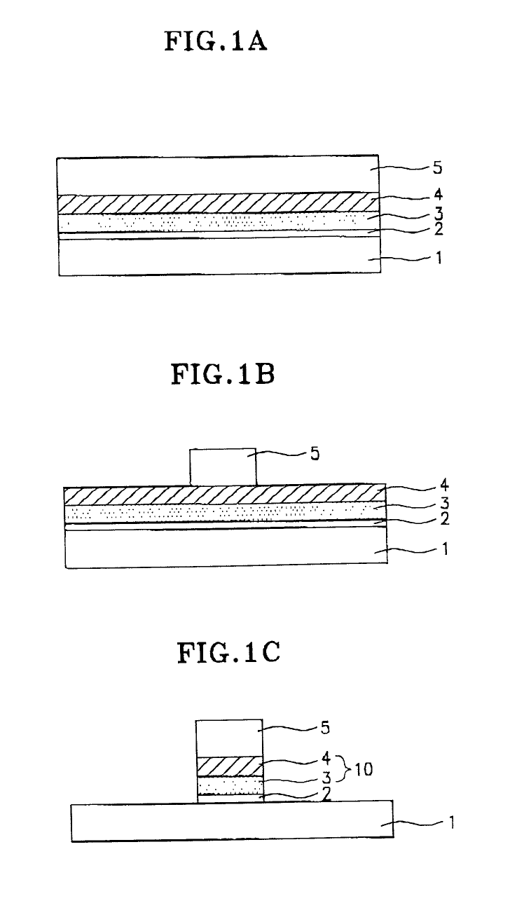

A method for forming a gate in accordance with a preferred embodiment of the present invention will now be described in detail with reference to FIG. 1A to 1C.

Referring to FIG. 1A, a gate oxide layer 2 is formed on a semiconductor substrate 1 according to a thermal treatment or deposition. A polysilicon layer 3, doped with an impurity such as P, As or B, is then deposited on the gate oxide layer 2. A Co-silicide layer 4 is then deposited on the polysilicon layer preferably using a physical deposition technique such as, for example, a sputtering process. A hard mask film 5 is then deposited on the Co-silicide layer 4. The hard mask film 5 is preferably used only as an etching mask, and consists of an oxide or nitride film. In addition, the hard mask film 5 is employed as an etching barrier during subsequent self-aligned contact processing.

As illustrated in FIG. 1B, the hard mask film 5 is patterned according to conventional photolithography and etch processes, thereby forming a hard mask film pattern 5a which defines a gate formation region and which is used as an etching mask during a succeeding process.

As depicted in FIG. 1C, the Co-silicide layer 4, polysilicon layer 3, and gate oxide layer 2, are sequentially etched by using the hard mask film pattern 5a as the etching mask, to form gate 10 having a stacked structure.

The Co-silicide layer 4, polysilicon layer 3 and gate oxide layer 2 may be etched using Cl₂ as the base etch gas. In addition, at least one gas or gas mixture selected from the group consisting of Ar, HBr, O₂ and He—O₂ gas may be mixed with the Cl₂ gas.

Although the Cl₂ gas can etch the Co-silicide layer, the etch rate is relatively independent of the general etching chamber configuration, but is remarkably dependent upon the electrode temperature, i.e., a temperature of the wafer chuck where the wafer is held during etch. Therefore, the electrode temperature is must be maintained over 70° C., preferably between 70 and 300° C., to obtain adequate etching of the Co-silicide.

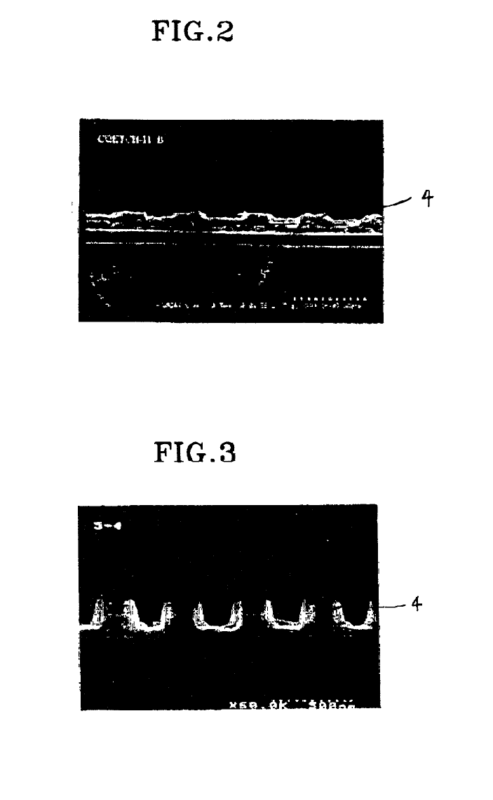

FIGS. 2 and 3 are photographs illustrating thus dependence on the electrode temperature for etching a gate conductive layer including Co-silicide layer using a Cl₂ base gas in accordance with the preferred embodiment of the present invention. Here, FIG. 2 is a photograph showing the etch result when the electrode temperature in the etching chamber is about 30° C., and FIG. 3 is a photograph showing the etch result when the electrode temperature in the etching chamber is about 70° C.

As shown in FIG. 2, when the electrode temperature is maintained at about 30° C., the gate conductive layer including the Co-silicide layer 4 is not etched uniformly, despite using the Cl₂ base gas.

Conversely, as shown in FIG. 3, when the electrode temperature is maintained at about 70° C., the gate conductive layer including the Co-silicide layer 4 is uniformly etched using the Cl₂ base gas.

As described above, the method for forming the gate in accordance with the present invention etches the gate conductive layer with Co-silicide layer 4 using the Cl₂ base gas at an electrode temperature of over 70° C., preferably between 70 and 300° C. On the other hand, when substrate temperature is monitored and controlled rather than the wafer chuck temperature, the substrate should be maintained at over 50° C., for instance between 50 and 250° C.

As discussed earlier, in accordance with the present invention, the Cl₂ base gas may be used as the etching gas for the Co-silicide layer. This produces a gate having the stacked structure of the polysilicon layer and the Co-silicide layer. Accordingly, the gate can provide a low resistance at even minute gate line widths, and thus is suitable for the fabrication of high integration devices.

On the other hand, although the present invention has been explained with regard to the gate formation, it can be readily applied to the conductive line formation, such as a bit line etch. In addition, the present invention can be applied to the formation of conductive lines comprising Co as well as those comprising Co-silicide.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. A method for forming a gate structure, the gate structure comprising stacked polysilicon and Co-silicide layers comprising the steps of:
forming a hard etch mask;
etching at least the Co-silicide and polysilicon layers while maintaining an electrode temperature of over 70° C. and using Cl₂ as the etching gas.

2. The method according to claim 1, wherein the step of etching is performed at a temperature range from 70° C. to 300° C.

3. The method according to claim 1, wherein the etching gas comprises a mixture of Cl₂ and Ar.

4. The method according to claim 11 wherein the etching comprises a mixture of Cl₂ and HBr.

5. The method according to claim 1, wherein the etching gas comprises of mixture of the Cl₂, Ar, and HBr.

6. The method according to claim 1, wherein the etching gas comprises Cl₂, Ar, HBr, and O₂.

7. The method according to claim 1, wherein the etching gas comprises a mixture of Cl₂, Ar, HBr and He—O₂.
